(19) United States
(12) Patent Application Publication
(10) Pub. No.: US 2007/0029678 A1
(43) Pub. Date: Feb. 8, 2007

(54) Lead-free solder

(76) Inventors: Kazuyuki Makita, Tokyo (JP); Masaki Ichinose, Tokyo (JP); Taketo Watashima, Tokyo (JP); Masayuki Soutome, Tokyo (JP); Mitsuo Yamashita, Tokyo (JP); Takeshi Asagi, Tokyo (JP); Masatoshi Hirai, Tokyo (JP); Toru Murata, Tokyo (JP)

Correspondence Address: YOUNG & THOMPSON, 745 SOUTH 23RD STREET, 2ND FLOOR, ARLINGTON, VA, 22202, US

(21) Appl. No.: 11/498,873

(22) Filed: Aug. 4, 2006

(30) Foreign Application Priority Data
Aug. 5, 2005 (JP) 2005-228841

(51) Int. Cl. H01L 23/48

(52) U.S. Cl. 257/772; 257/E23.023

(57) ABSTRACT

According to one embodiment of the invention, there is provided a lead-free solder including an alloy rolled into a shape of sheet. The alloy includes: tin; from 10 wt % to less than 25 wt % of silver; and from 3 wt % to 5 wt % of copper. The alloy is free from lead.

### BACKGROUND OF THE INVENTION

1. Field of the Invention

The present invention relates to a lead-free solder that does not contain lead.

2. Description of the Related Art

A tin (Sn) based solder contains lead, which is soft, as a base material so that a thin tin-based solder having a thickness of several micrometers to tens of micrometers can be easily obtained. Therefore, conventionally, the tin-based solder has been widely used for soldering in semiconductor device. However, in order to prevent environmental pollution by lead, in 2007, as a substitute for the lead solder, a solder that does not contain lead, that is, a lead-free solder must be used. Accordingly, the lead-free solder has been developed.

In general, an Sn—Ag (silver) based solder and an Sn—Sb (antimony) solder are known as the lead-free solder. However, since the lead-free solder does not contain lead, a thin lead-free solder can not be easily obtained. For example, JP-A-2004-146462 discloses a thin-plate shaped lead-free solder generated by sintering fine powder materials of solder that does not contain lead in a thin-plate shape. The lead-free solder is a sintered structure of metal powder.

In addition, a solder foil is proposed that is formed by rolling a material containing particles of copper (Cu), silver, and tin in use of connection of electronic parts (for example, see JP-A-2004-247742). The solder foil is not an alloy solder. In addition, JP-A-11-97618 discloses a method of joining semiconductor wafers. In the method, an aluminum layer, or aluminum and nickel layers are inserted between the wafers, and the resulting product is heated under pressure, so that a stacked wafer structure constructed by stacking a plurality of the wafers is obtained.

### SUMMARY OF THE INVENTION

However, the solder disclosed in JP-A-2004-146462 or JP-A-2004-247742 has to be powdered in a fabricating process, so that the number of processes increases. Therefore, there is a problem of an increase in costs. When the powered solder is creamed instead of being thin solder, there is the same problem. In addition, in the method of joining wafers disclosed in JP-A-11-97618, the semiconductor wafers can be joined without the solder. However, in the method, the thin lead-free solder is not used to join the semiconductor wafers.

The present invention has made in view of above circumstances and provides a low-cost lead-free solder not requiring powdering the solder or materials of the solder, to produce a thin sheet-shaped lead-free solder.

According to an aspect of the invention, there is provided a lead-free solder including an alloy rolled into a shape of sheet. The alloy includes: tin; from 10 wt % to less than 25 wt % of silver; and from 3 wt % to 5 wt % of copper. And the alloy is free from lead.

The alloy may include 10 wt % to 20 wt % of silver. The alloy may have a shape of sheet with a thickness from 40 μm to 120 μm. The alloy may have a shape of a disk with the same diameter as a joined member, for example, a semiconductor wafer.

According to another aspect of the invention, the solder or materials thereof are not powdered, and thin sheet-shaped lead-free solder which is an alloy containing tin, silver, and copper as main components can be obtained.

The lead-free solder according to the present invention has an advantage in that, the solder and materials thereof are alloyed and rolled in a shape of a thin sheet without powdering the solder and materials thereof, so that costs are reduced.

### BRIEF DESCRIPTION OF THE DRAWINGS

Embodiments of the present invention will be described in detail based on the following figures, wherein:

FIG. 1 is a sectional view of a stacked wafer structure constructed using a solder in a fabricating process according to an embodiment of the present invention;

FIG. 2 is a sectional view of the stacked wafer structure constructed using the solder in the fabricating process according to the embodiment of the present invention;

FIG. 3 is a schematic sectional view of a heating pressing soldering device used in the fabricating process for the stacked wafer structure using the solder according to the embodiment of the present invention;

FIG. 4 is a schematic plan view of a pressing stacking jig used in the fabricating process for the stacked wafer structure using the solder according to the embodiment of the present invention;

FIG. 5 is a side elevation view of the pressing stacking jig shown in FIG. 4;

FIG. 6 is a schematic sectional view of a belt conveyer used in the fabricating process for the stacked wafer structure using the solder according to the embodiment of the present invention;

FIG. 7 is a schematic sectional view of a vacuum heater used in the fabricating process for the stacked wafer structure using the solder according to the embodiment of the present invention; and

FIG. 8 is a schematic view for explaining a solder heat-resistance test.

### DETAILED DESCRIPTION OF THE INVENTION

Hereinafter, a lead-free solder according to an embodiment of the present invention will be described in detail with reference to the accompanying drawings. The lead-free solder according to the embodiment includes an alloy containing tin, silver, and copper as main components. A composition ratio of the silver may be in a range from 10 wt % to less than 25 wt %, preferably 20 wt %, based on the total amount of the alloy. A composition ratio of the copper may be in a range from 3 wt % to 5 wt %, preferably 5 wt %, based on the total amount of the alloy. The balance or a portion of the balance is tin. For example, as the lead-free solder, there are Sn-10Ag-5Cu solder containing silver of 10 wt % and copper of 5 wt %, Sn-20Ag-5Cu solder containing silver of 20 wt % and copper 5 wt %. In addition, the lead-free solder contains unavoidable element.

The lead-free solder is rolled in a shape of a sheet. A thickness of the lead-free solder may be in a range from 40 μm to 120 μm, but not limited thereto. In case of fabricating a stacked wafer structure constructed by joining semiconductor wafers by solder, a range of the thickness is determined based on a thickness of a wafer, the number of wafers to be stacked, and a thickness of the predetermined number of wafers joined by the solder. In addition, a shape and a size of the solder may be same as those of joined members. For example, when the joined members are the semiconductor wafers, the solder may have a shape of a disk with the same diameter as those of the wafers.

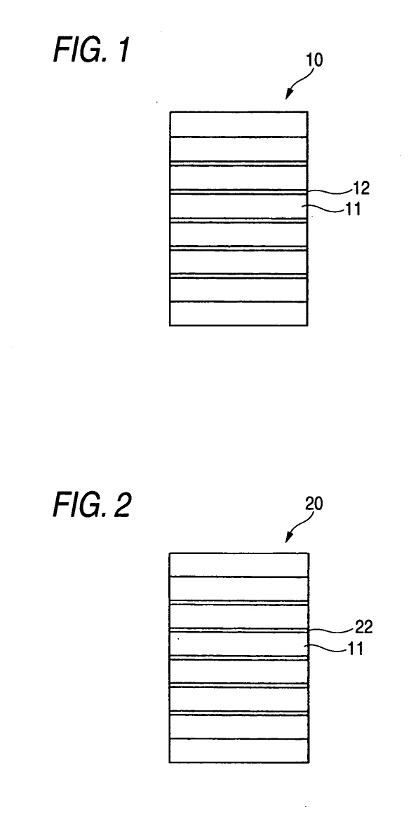

FIGS. 1 and 2 are schematic views for explaining a process for fabricating the stacked wafer structure using the solder according to the embodiment. FIGS. 1 and 2 show sectional views of the stacked wafer structure. As shown in FIG. 1, firstly, a plurality of wafers 11 and lead-free solder 12 alternatively stacked, so that a stacked wafer solder structure 10 is formed.

Next, the stacked wafer solder structure 10 is heated under pressure to melt the lead-free solder 12, and as shown in FIG. 2, a stacked wafer structure 20 constructed by soldering the wafers 11 by a solder layer 22 is obtained. Here, an joining temperature ranges from a temperature (hereinafter, denoted by “solder solidus line temperature +30° C.”) which is higher than a temperature of the solidus line of the solder 12 by 30° C. to a temperature (hereinafter, denoted by “solder liquidus line temperature −30° C.”) which is lower than a temperature of the liquidus line of the solder 12 by 30° C.

After a chip of the stacked wafer structure 20 is cut, solder heat-resistance test where the chip is heated for ten seconds at a temperature of 260° C. three times is performed in the state that both end portions of the stacked wafer structure in a direction of stacking are supported. The minimum temperature for passing the test is the solder solidus line temperature +30° C. In addition, since the melted solder becomes homogenous at a temperature higher than the solder solidus line temperature +30° C., a liquid solder having low melting point is pushed outside the joined members, and an advantage of improving the solder heat-resistance is lost.

In addition, during soldering, a pressure for pressing the stacked wafer solder structure 10 may be in a range from 1 MPa to 10 MPa, preferably, from 3 MPa to 7 MPa. This is because the all wafers can be joined above the pressure of 1 MPa. In addition, the wafers can be easily broken above the pressure of 10 MPa. By the pressing and the heating, the heat-resistance of the solder layer 22 is improved.

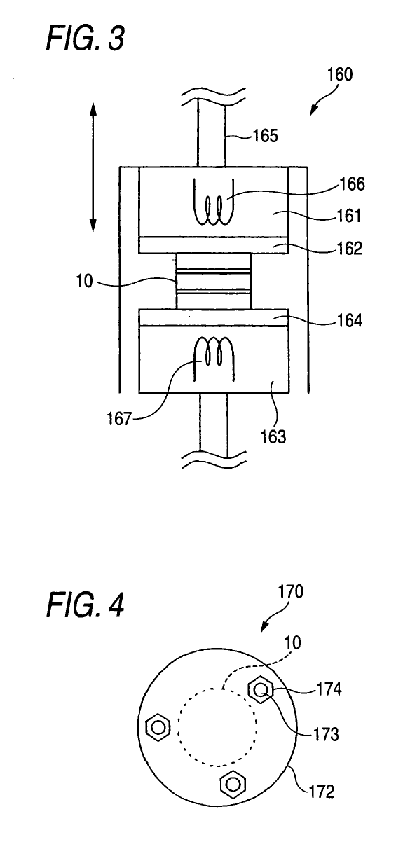

In order to obtain the stacked wafer structure 20 shown in FIG. 2, for example, a heating pressing soldering device 160 is used as shown in FIG. 3. The stacked wafer solder structure 10 is inserted between an upper uniform heating pressing plate 162 of an upper press body 161 and a lower uniform heating pressing plate 164 of a lower press body 163. After that, the upper press body 161 is descended by a press arm 165, so that the stacked wafer solder structure 10 is pressed. In this state, the stacked wafer solder structure 10 is heated by heaters 166 and 167 included in the upper and lower press bodies 161 and 163, respectively. As an example of the heating method, an induction heating may be used.

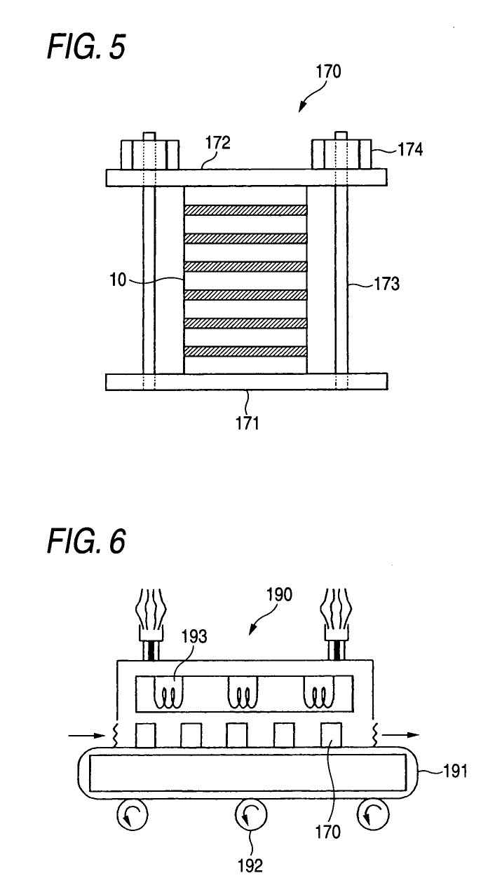

Alternatively, in order to press the stacked wafer solder structure 10, as shown in a plan view of FIG. 4 and a side elevation view of FIG. 5, a pressing stacking jig 170 is used. In this case, the stacked wafer solder structure 10 is inserted between lower and upper plates 171 and 172 of the jig 170. Next, the stacked wafer solder structure 10 is pressed by tightening nuts 174 which are screw-jointed to screw portions of the top portions of a plurality of bar-shaped members 173 serving as columns connecting the lower and upper plates 171 and 172.

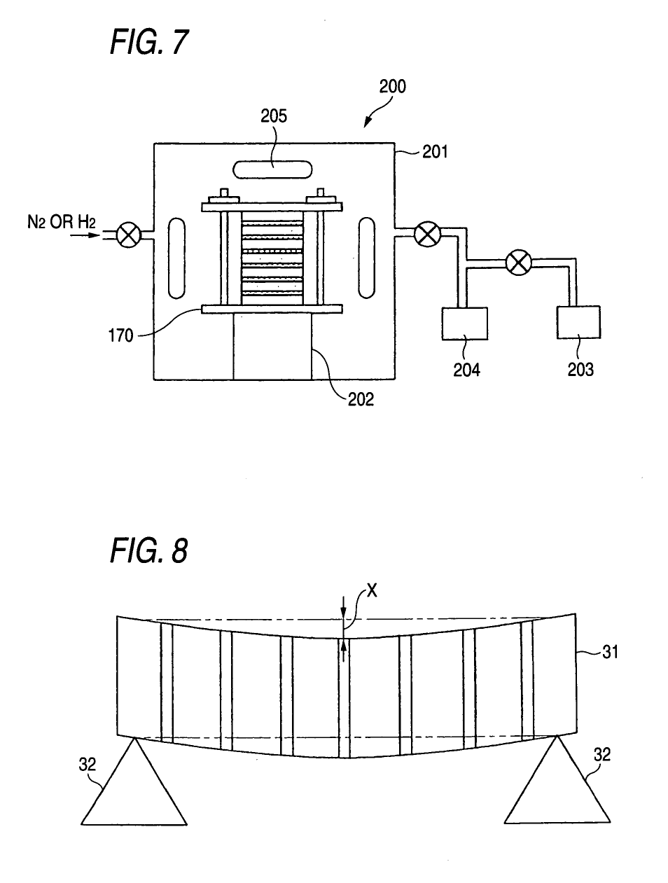

In the case where the pressing stacking jig 170 is used, for example, as shown in FIG. 6, the pressing stacking jig 170 pressing the stacked wafer solder structure 10 is arrayed on a belt 191 of a belt conveyer 190, and the belt 191 is moved by rotation of a rotator 192, so that the jig 170 is moved below a heater 193 and heated. Alternatively, as shown in FIG. 7, in a case where a vacuum heater 200 is used, the pressing stacking jig 170 pressing the stacked wafer solder structure 10 is disposed on a sample stage 202 in a vacuum chamber 201 of the vacuum heater 200, the chamber 201 is evacuated in vacuum by an ion pump 203 and a cryogenic pump 204, and the jig 170 is heated by a heater 205. Here, inert gas such as H₂ and N₂ may be introduced into the chamber 201.

The inventor tests the solder having various compositions for rolling characteristics, at the same time, fabricates the stacked safer structure 20 shown in FIG. 2, cuts a chip thereof, and test the chip for solder heat-resistance. The results are as follows. Compositions of the solder, solidus and liquidus temperatures, and temperatures and pressures in a fabricating process for the stacked wafer structure 20 are shown in Table 1.

TABLE 1

| | | | | | stacked structure | | |
|---|---|---|---|---|---|---|---|
| | | | | | | | heat |
| | | | | | | | resistance |
| | | | | | | | of |
| | | solder | | | | | solder |
| | composition | solidus | liquidus | rolling | soldering | soldering | (260° C. × 10 |
| | of | temperature | temperature | characteristics | temperature | pressure | seconds, |
| embodiment | solder | (° C.) | (° C.) | (φ100 mm × 40 μm) | (° C.) | (MPa) | 3 times) |
| 1 | Sn5Ag5Cu | 227.5 | 350 | ◯ | 260 | 3.6 | X |
| 2 | Sn10Ag5Cu | 227.5 | 355 | ◯ | 260 | 3.6 | ◯ |
| 3 | Sn15Ag5Cu | 227.5 | 363 | ◯ | 260 | 3.6 | ◯ |
| 4 | Sn20Ag1Cu | 227.5 | 363 | ◯ | 260 | 3.6 | X |
| 5 | Sn20Ag3Cu | 227.5 | 364 | ◯ | 260 | 3.6 | ◯ |
| 6 | Sn20Ag5Cu | 227.5 | 366 | ◯ | 230 | 3.6 | X |
| 7 | | | | | 260 | 3.6 | ◯ |
| 8 | | | | | | 7 | ◯ |
| 9 | | | | | | 10 | ◯ |
| 10 | | | | | 290 | 1 | ◯ |
| 11 | | | | | | 3.6 | ◯ |
| 12 | | | | | | 7 | ◯ |
| 13 | | | | | 320 | 3.6 | ◯ |
| 14 | | | | | 350 | 3.6 | X |
| 15 | Sn25Ag5Cu | 227.5 | 375 | X | | | |
| 16 | Sn30Ag5Cu | 227.5 | 390 | X | | | |

◯: good
X: bad

In the rolling characteristics tests for the solder, ingots of solder alloys having various components are fabricated, and each ingot is tested whether or not the ingot is rolled in a shape of a sheet having a diameter of 100 mm and a thickness of 40 μm. The results are shown in Table 1. In a column of rolling characteristics in Table 1, the symbol O represents the solder which can be rolled, and the symbol X represents the solder which can not be rolled. In Table 1, in a case where a composition ratio of the silver is in a range from 5 wt % to 20 wt %, and a composition ratio of the copper is in a range from 1 wt % to 5 wt %, it can be seen that the solder has the good rolling characteristics. The solder having the good rolling characteristics has the rolling characteristics equal to or better than that of the tin-based solder having lead as a base material. On the contrary, in a case where a composition ratio of the silver is 25 wt % or 30 wt %, the solder has the bad rolling characteristics, so that the solder can not be rolled in desired size and thickness.

In the solder heat-resistance tests, by using the solder which can be rolled in a shape of a desired sheet in the rolling characteristics tests, the solders and 20 wafers are stacked each other and soldered on conditions of various temperatures and pressures. The obtained stacked wafer structure is cut into chips having a size of 0.5 mm×0.5 mm by a wire saw. As shown in FIG. 8, after both end portions of the chip 31 in a direction of stacking are supported by supporting members 32, the chip 31 is heated for ten seconds at a temperature of 260° C. three times. After heating, a bending amount of x of the center of the chip 31 is measured. And it is tested whether or not the x is less than a predetermined value, for example, 50 μm. The results are shown in Table 1. In the solder heat-resistance column of FIG. 1, the symbol O represents the x which is less than 50 μm, and the symbol X represents the x which is more than 50 μm.

In Table 1, in a case where the solder containing a silver of which composition ratio is in a range from 10 wt % to 20 wt %, and a copper of which composition ratio is in a range from 3 wt % to 5 wt % is used, a soldering temperature ranges from the solder solidus line temperature +30° C. to the solder liquidus line temperature −30° C., and a soldering pressure is in a range from 1 MPa to 10 MPa, the good solder heat-resistance can be obtained. The solder having good solder heat-resistance has the solder heat-resistance equal to or better than that of the tin-based solder having lead as a base material.

On the contrary, although the solder has the good 20: rolling characteristics, in a case where the solder contains the silver of which composition ratio is 5 wt %, or the copper of which composition ratio is 1 wt % is used, or in a case where the soldering temperature is less than solder solidus line temperature +30° C., or the soldering temperature is more than the solder liquidus line temperature −30° C., the good solder heat-resistance can not be obtained. In addition, the inventor fabricates the stacked wafer structure using the solder having a composition for good rolling characteristics in a good heat-resistance condition and assembles semiconductor devices by using chips obtained from the stacked wafer structure. According to the embodiments, it is possible to obtain initial electric characteristics and reliability equivalent to those of a conventional tin-based solder having lead as a base material.

As described above, according to the embodiments, the thin solder having a shape of a sheet is obtained by rolling the ingot of solder alloy, so that there is no need to powder the solder or materials thereof. Therefore, the low-cost solder having a shape of a thin plate without lead con be obtained. In addition, in case of fabricating the stacked structure using the solder, the solder obtains the solder heat-resistance equal to that of the conventional solder or more.

The present invention is not limited to the embodiments, and various modifications are available. For example, the composition ratios and sizes described in the embodiments are simply exemplified values, and the present invention is not limited thereto.

Accordingly, a lead-free solder according to the embodiments may be used for a thin lead-free solder having a shape of a sheet, and more particularly, for a solder used in a fabricating process for stacked wafer structure constructed by soldering a plurality of semiconductor wafers.

What is claimed is:

1. A lead-free solder comprising:
an alloy rolled into a shape of sheet, the alloy comprising:
tin;
from 10 wt % to less than 25 wt % of silver; and
from 3 wt % to 5 wt % of copper;
wherein the alloy is free from lead.

2. The lead-free solder according to claim 1, wherein the alloy comprises 10 wt % to 20 wt % of silver.

3. The lead-free solder according to claim 1, wherein the alloy has a shape of sheet with a thickness from 40 μm to 120 μm.

4. The lead-free solder according to claim 1, wherein the alloy has a shape of a disk with the same diameter as a joined member.
